(19) United States
(12) Patent Application Publication
(10) Pub. No.: US 2020/0083623 A1
(43) Pub. Date: Mar. 12, 2020

(54) DUAL IN-LINE MEMORY MODULES AND CONNECTORS FOR INCREASED SYSTEM PERFORMANCE

(71) Applicant: INTEL CORPORATION, Santa Clara, CA (US)

(72) Inventor: Yi HUANG, Shanghai (CN)

(21) Appl. No.: 16/465,128

(22) PCT Filed: Dec. 30, 2016
(86) PCT No.: PCT/CN2016/113388

§ 371 Date: May 29, 2019

(51) Int. Cl. H01R 12/72; H05K 1/11; H01R 12/71; H01R 43/26

(52) U.S. Cl. CPC H01R 12/72; H05K 1/111; H05K 2201/10159; H01R 43/26; H05K 2201/09409; H01R 12/718

(57) ABSTRACT

A dual in-line memory module (DIMM) and connector are described. The DIMM may include a substrate including first and second sides and a plurality of memory chips on at least one of the sides. The first and second sides each include an end region configured to engage a connector. The DIMM may include a plurality of rows of electrical contacts positioned in the end region on the first side of the substrate, the plurality of rows including a first side first row of electrical contacts and a first side second row of electrical contacts. The DIMM may include a plurality of rows of electrical contacts positioned in the end region on the second side of the substrate, the plurality of rows including a second side first row of electrical contacts and a second side second row of electrical contacts. Other embodiments are described and claimed.

### TECHNICAL FIELD

Embodiments related generally to memory modules and connectors for coupling memory modules to a board.

### BACKGROUND

Computing systems may include a board such as a motherboard on which is positioned a processor and a plurality of dual in-line memory modules (DIMMs). The computing system performance may be limited when using high performance processors due to the motherboard structure having an insufficient area to connect a sufficient quantity of dual in-line memory modules to take advantage of the high performance capabilities of the processor.

### BRIEF DESCRIPTION OF THE DRAWINGS

Embodiments are described by way of example, with reference to the accompanying drawings, in which like reference numerals may refer to similar elements.

FIG. 1 illustrates a dual in-line memory module (DIMM) including two rows of contacts, in accordance with certain embodiments.

FIG. 2 illustrates a side view of a DIMM including memory devices positioned on opposite sides thereof, in accordance with certain embodiments.

FIG. 3 illustrates a side view of a DIMM including memory devices positioned on one side, in accordance with certain embodiments.

FIG. 4 illustrates a cross-sectional view of a DIMM connector, in accordance with certain embodiments.

FIG. 5 illustrates a view of the DIMM connector of FIG. 4.

FIG. 6 illustrates a system including the DIMM of FIG. 2 positioned in a connector, in accordance with certain embodiments.

FIG. 7 illustrates a system including the DIMM of FIG. 3 positioned in a connector, in accordance with certain embodiments.

FIG. 8 illustrates a DIMM, in accordance with certain embodiments.

FIG. 9 illustrates a system including a DIMM including a plurality of memory devices on opposite sides, the DIMM positioned in a connector, in accordance with certain embodiments.

FIG. 10 illustrates a system including a DIMM including a plurality of memory devices on one side, the DIMM positioned in a connector, in accordance with certain embodiments.

FIG. 11 illustrates a DIMM including two rows of offset contacts, in accordance with certain embodiments.

FIG. 12 illustrates a cross sectional view of a DIMM connector, in accordance with certain embodiments.

FIG. 13 illustrates a view of the DIMM connector of FIG. 12.

FIG. 14 illustrates a system including a DIMM positioned in the connector of FIG. 12, in accordance with certain embodiments.

FIG. 15 illustrates a DIMM including two rows of contacts, in accordance with certain embodiments.

FIG. 16 illustrates a cross sectional view of a DIMM connector configured to accept the DIMM of FIG. 15, in accordance with certain embodiments.

FIG. 17 illustrates a view of the DIMM connector of FIG. 16.

FIG. 18 illustrates a system including a DIMM positioned in the connector of FIG. 16, in accordance with certain embodiments.

FIG. 19 illustrates a DIMM including two rows of offset contacts, in accordance with certain embodiments.

FIG. 20 illustrates a cross sectional view of a DIMM connector configured to accept the DIMM of FIG. 19, in accordance with certain embodiments.

FIG. 21 illustrates a view of the DIMM connector of FIG. 20.

FIG. 22 illustrates a system including a DIMM positioned in the connector of FIG. 20, in accordance with certain embodiments.

FIG. 23 illustrates a side view of a DIMM including memory devices positioned on opposite sides thereof, in accordance with certain embodiments.

FIG. 24 illustrates a cross sectional view of a DIMM connector configured to accept the DIMM of FIG. 23, in accordance with certain embodiments.

FIG. 25 illustrates a side view of a DIMM including memory devices positioned on opposite sides thereof, in accordance with certain embodiments.

FIG. 26 illustrates a cross sectional view of a DIMM connector configured to accept the DIMM of FIG. 25, in accordance with certain embodiments.

FIG. 27 illustrates a DIMM including a single row of contacts on a side thereof.

FIG. 28 illustrates a board including a microprocessor positioned between two sets of three DIMMs.

FIG. 29 illustrates a DIMM including two rows of contacts on a side thereof, in accordance with certain embodiments.

FIG. 30 illustrates a board including a microprocessor positioned between two sets of six DIMMs, in accordance with certain embodiments.

FIG. 31 illustrates a flowchart of operations in accordance with certain embodiments.

FIG. 32 illustrates and electronic system arrangement in which embodiments may find application.

### DESCRIPTION OF EMBODIMENTS

References in the specification to “embodiments,” “certain embodiments,” “an embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Certain embodiments relate to DIMMs and connectors that accept DIMMs. Embodiments include devices and methods.

Certain embodiments relate to a DIMM structure that includes a board having a staggered or stepped configuration that utilizes multiple rows of contacts (also known, for example, as pins, fingers, and/or pads), with each row on a different plane. Certain embodiments relate to a DIMM structure that includes a board having a configuration that utilizes multiple rows of contacts on the same plane. By having multiple rows of contacts, the DIMM may have a shorter length to have the same number of contacts as a conventional DIMM having a single row of contacts. For example, a DIMM utilizing two rows of contacts (pins) on each side of the DIMM may, in certain embodiments, have about half the printed circuit board footprint of a conventional DIMM and include the same number of contacts. By making the DIMM shorter in length, more DIMMs may fit into a memory area on a board. The use of a greater numbers of DIMMs can lead to greater memory bandwidth and increased performance.

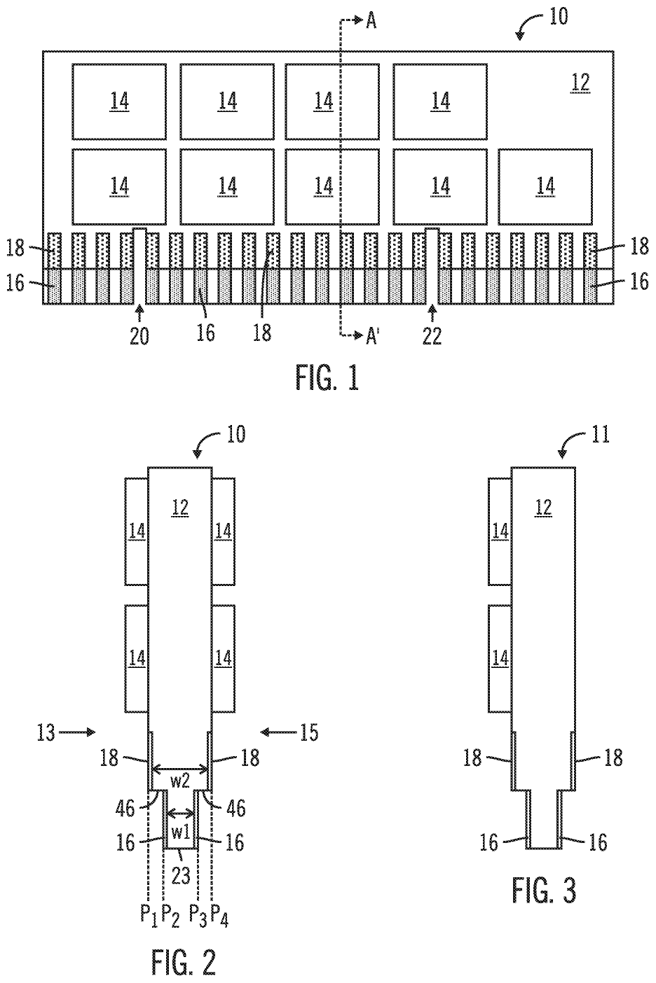

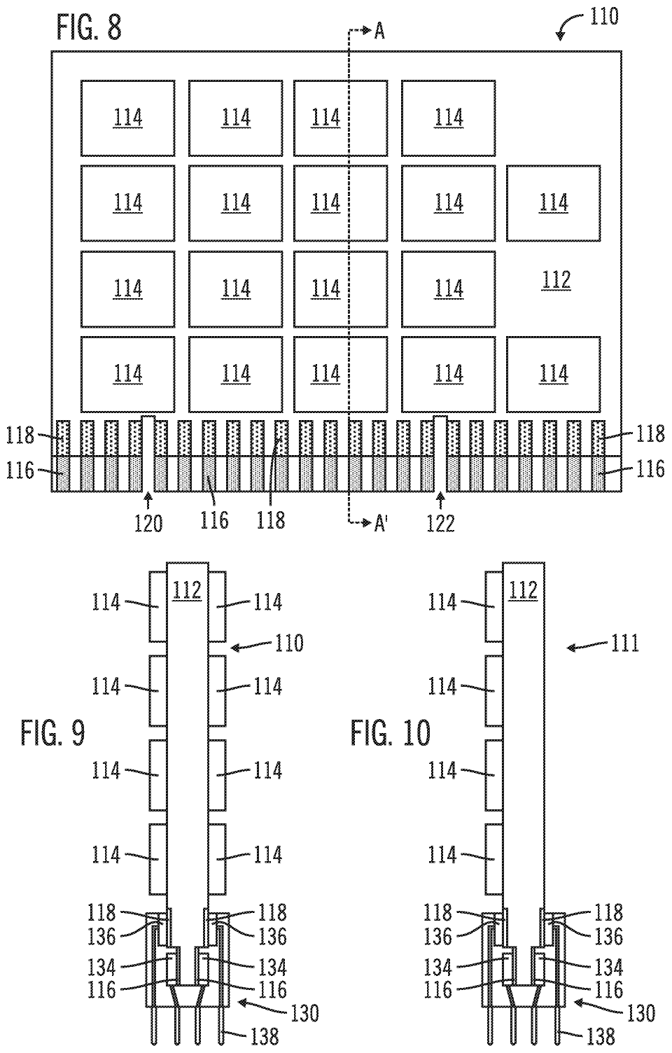

FIG. 1 illustrates a DIMM structure 10 including a substrate 12, such as a circuit board, on which one or more memory chips 14 are positioned. Other components including, but not limited to, resistors, capacitors, and the like (not illustrated) may also be positioned on the substrate 12. Two rows of contacts 16, 18 are positioned on the substrate 12. The contacts 16, 18 are shaded differently in FIG. 1 so that their relative position can be readily ascertained. (FIGS. 8, 11, 15, and 19 are similarly shaded) The contacts 16, 18 may be electrically coupled to the memory chips 14 and/or other components of the DIMM 10 in any suitable manner, for example, along the surfaces or within layers in the substrate 12.

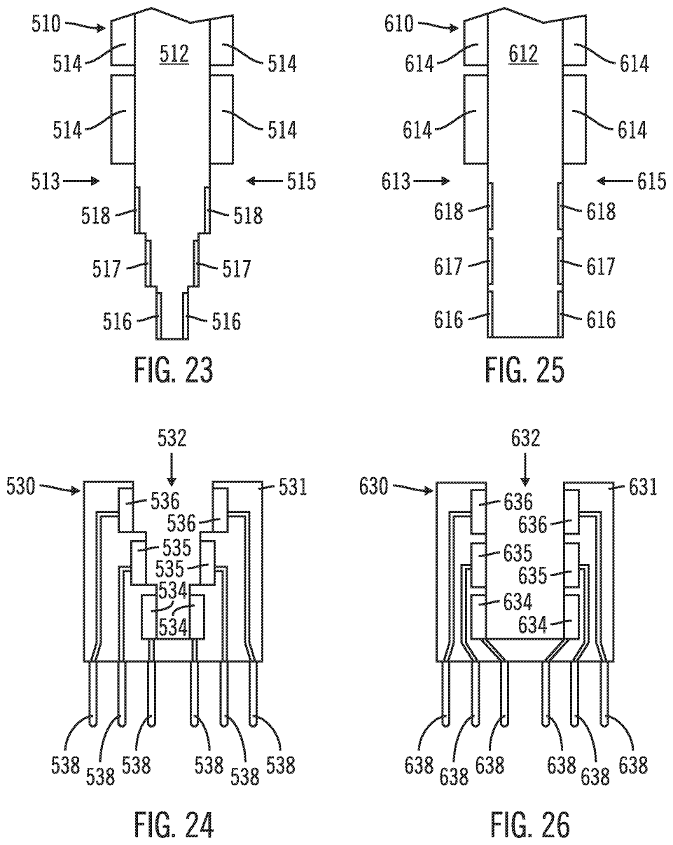

The contacts 16 may in certain embodiments be aligned with the contacts 18 as illustrated in FIG. 1, with the side edges of the contacts 18 lined up with the side edges of the contacts 16. In addition, as illustrated in FIG. 1, the lower edges of the contacts 18 are at about the same vertical height as the upper edges of the contacts 16. In other embodiments, the lower edges of the upper contacts may be at a different vertical height than the upper edges of the lower contacts. For example, FIG. 23 illustrates an embodiment where the contacts are spaced apart from one another in a vertical manner, with the lower edge of contact 518 being positioned at a different vertical position than the upper edge of contact 517.

In addition, the DIMM 10 of FIG. 1 includes a stepped surface, with the lower row contacts 16 being positioned on a different level than the upper row contacts 18. This may be more easily seen in FIG. 2, which illustrates lower row contacts 16 on each side 13, 15 of the DIMM 10 being positioned on a first level that is separated from the upper contacts 18 on a second level by ledges 46 on each side 13, 15 of the DIMM. The contacts 16, 18 may be formed, for example, as gold or copper structures (also known as pins, fingers, or pads) that are electrically coupled to, for example, traces (not shown) that lead to the various memory chips 14 and/or other components or features on the substrate. The DIMM 10 may also include one or more key openings 20, 22 that may assist in positioning and holding the DIMM 10 in place in a connector.

FIG. 2 illustrates a side cross-sectional view of the DIMM 10 of FIG. 1 along the dotted line A-A′. The DIMM 10 includes memory chips 14 on both sides 13, 15 of the substrate 12. As seen in FIG. 2, the DIMM 10 includes an end region configured to engage a connector and including a stepped or staggered structure in which the thickness is decreased. The lower end 23 of the DIMM 10 acts as a leading edge when the DIMM 10 is positioned in a connector. Contacts 16 are positioned on the decreased thickness portion w1 of the end region, while contacts 18 are positioned on the larger thickness portion w2 of the end region of the DIMM 10. The contacts 16 and 18 are on different steps (or levels) of the substrate 10 structure. Moving along FIG. 2 from left to right, the contacts 18 on the side 13 of the DIMM extend along a first plane P₁, the contacts 16 on the side 13 extend along a second plane P₂ spaced inward from the first plane P₁, the contacts 16 on the side 15 extend along a third plane P₃, and the contacts 18 on the side 15 extend along a fourth plane P₄.

While FIG. 2 illustrates DIMM 10 with memory chips on both sides of the substrate 12, embodiments may also include a DIMM 11 with memory chips on only one side of the substrate 12, as illustrated in FIG. 3.

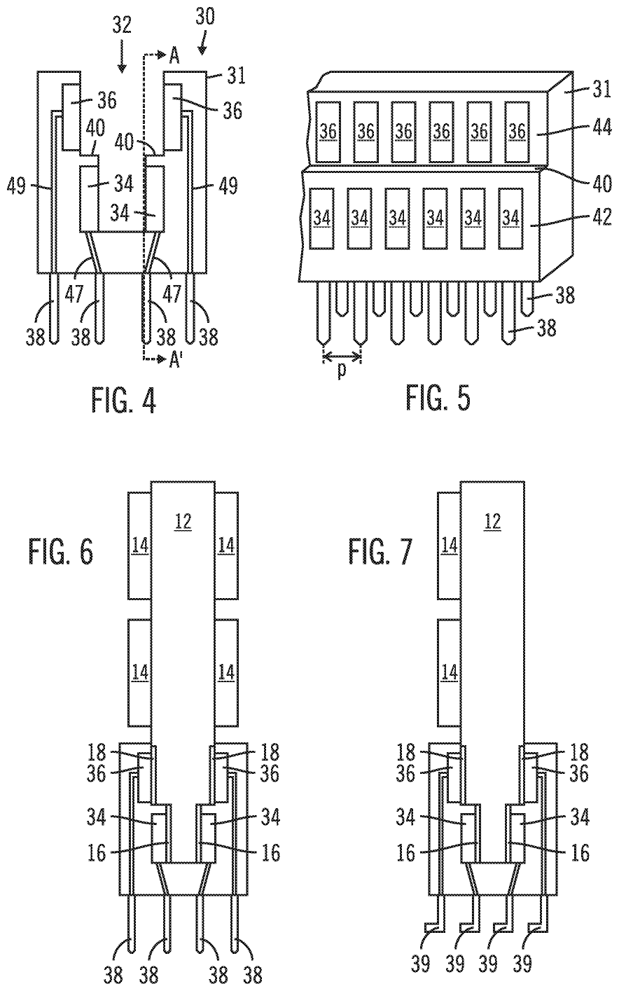

FIG. 4-5 illustrate a connector 30 configured to accept a DIMM such as illustrated in FIGS. 1-3. The connector 30 (also known as a DIMM socket) includes a housing 31 and defines an interior region 32 sized and shaped to accommodate a stepped DIMM structure such as that illustrated in FIG. 2. The connector 30 includes a plurality of electrically conductive contact regions that may be configured, for example, as pads or pins to electrically couple the connector with a DIMM. As illustrated in FIGS. 4-5, the connector 30 includes lower pads 34 and upper pads 36 configured to engage the contacts from a DIMM, with the upper pads 36 at least partially defining a larger width portion of the opening 32 and the lower pads 34 at least partially defining a smaller width portion of the opening 32. The connector 30 includes the upper pads 36 and the lower pads 34 positioned on different steps of the connector 30, with a ledge surface 40 extending between the steps. The pads 34, 36 are electrically coupled to suitable connector contact structures for electrical connection to a structure such as a printed circuit board (for example, a motherboard). The electrical connection to the structure may be made using any suitable connection, including, but not limited to, through hole or surface mounting methods. The connector pins 38 illustrated in FIG. 4-5 are an example of an electrical connection structure. As seen in FIG. 4, electrical pathways 47, 49 extend between the pads 34, 36 and the connection pins 38. The connector pins 38 may be spaced any suitable distance apart from one another. In certain embodiments, the connector pins 38 have a pitch p (as seen in FIG. 5, the spacing between adjacent contacts 38 in a row) of about 0.8 to about 1.0 mm. In certain embodiments, any suitable attachment mechanism may be used to attach (lock and unlock) one or both ends of the DIMM into the connector. In certain embodiments only one end is locked into the connector. Such one end locking may be useful when two connectors are positioned so that one end of the first connector is very close to an end of the second connector, and access to locking mechanisms at these closely positioned ends would be difficult.

FIG. 5 illustrates a view of the connector 30 along the dashed line A-A′ of FIG. 4. The stepped structure of the connector 30 is apparent, with the lower pads 34 positioned on a different step (level) than the upper pads 36. As seen in FIG. 5, the lower pads 34 are positioned along the surface 42, and upper pads 36 are positioned along the surface 44. A ledge surface 40 is positioned between the surface 42 and surface 44.

FIGS. 6-7 illustrate views of the DIMMs of FIGS. 2-3 inserted into a connector. The lower contacts 16 on the DIMMs are positioned in electrical contact with the lower pads 34 in the connector, and the upper contacts 18 on the DIMMs are positioned in electrical contact with the upper pads 36 in the connector. In certain embodiments, the same type of connector may be used regardless of whether the DIMM includes memory chips on one side or on two sides of the DIMM. FIG. 6 illustrates a connector including pins 38 for a through hole connection, whereas FIG. 7 illustrates a connector including pins 39 for a surface mount connection. The pins 39 may have a backwards L shape. In certain embodiments, the pin 39 spacing may be about 1 mm. As noted above, any type of suitable connection may be used in various embodiments.

Embodiments may relate to a variety of DIMM structures. For example, certain conventional low density DIMMs may include a single row of memory chips on one or both sides of a substrate, and a single row of contacts along each side of the substrate to couple to DIMM to a board. By placing multiple rows of contacts on one or both sides of a substrate, and placing multiple rows of memory chips on one or both sides of the substrate, embodiments allow for the formation of DIMMs having a smaller form factor than conventional DIMM structures. For example, one type of conventional low density DIMM may have a length of about 133.35 mm and a height of about 31.25 mm, with a single row of memory chips and a single row of contacts on each side. The embodiment illustrated in FIG. 1, for example, shows two rows of memory chips and two rows of contacts. By including two rows, the form factor can be made smaller because more memory chips and more contacts can fit into the same length of substrate. As a result, in certain embodiments, a structure such as illustrated in FIG. 1 may have a length of about 66.67 mm and a height of about 31.25 mm. Thus, two DIMMs 10 such as illustrated in FIG. 1 positioned side by side may have about the same form factor when mounted to a board as a single conventional low density DIMM.

Similarly, certain conventional high density DIMMs may include two rows of memory chips and a single row of contacts on a side. Certain embodiments may include a DIMM structure including more than two rows of memory chips. FIG. 8 illustrates an embodiment of a DIMM 110 including four rows of memory chips 114 positioned on a substrate 112, together with two rows of contacts 116, 118, and key regions 120, 122. The memory chips 114 and contacts 116, 118 may be the same or similar to those in the embodiment illustrated in FIGS. 1-2. The substrate 112 may have a similar multi-level structure, but may have larger height than the substrate 12 to accommodate the additional rows of memory chips 114. The contacts 116, 118 may be configured in the same manner as the contacts 16, 18 discussed above, including a first level of contacts 116 and a second level of contacts 118. FIG. 9 illustrates a side cross-sectional view of the DIMM 110 along the line A-A′, inserted into a connector 130, including pads 134, 136, and connections such as connector pins 138, which may be the same or similar to those described above in the discussion of the connector 30. Embodiments may also include a DIMM 111 with four rows of memory chips 114 on only one side of the substrate 112, as illustrated in FIG. 10, which shows such the DIMM 111 positioned in a connector 130.

Certain conventional high density DIMMs may include a two rows of memory chips on one or both sides of a substrate, and a single row of contacts along each side of the substrate to couple to DIMM to a board. For example, one type of conventional high density DIMM may have a length of about 133.35 mm and a height of about 31.25 mm. By including multiple rows of contacts on each side of the substrate, the form factor can be made smaller because more contacts can fit into the same length of substrate. As a result, in certain embodiments, a structure such as illustrated in FIG. 8 may have a length of about 66.67 mm and a height of about 62.5 mm. The additional height is to accommodate the additional rows of memory chips. Thus, two DIMMs 110 such as illustrated in FIG. 8 positioned side by side may have about the same form factor on a board as a single conventional high density DIMM, although, as noted above, the DIMM 110 may have a greater height.

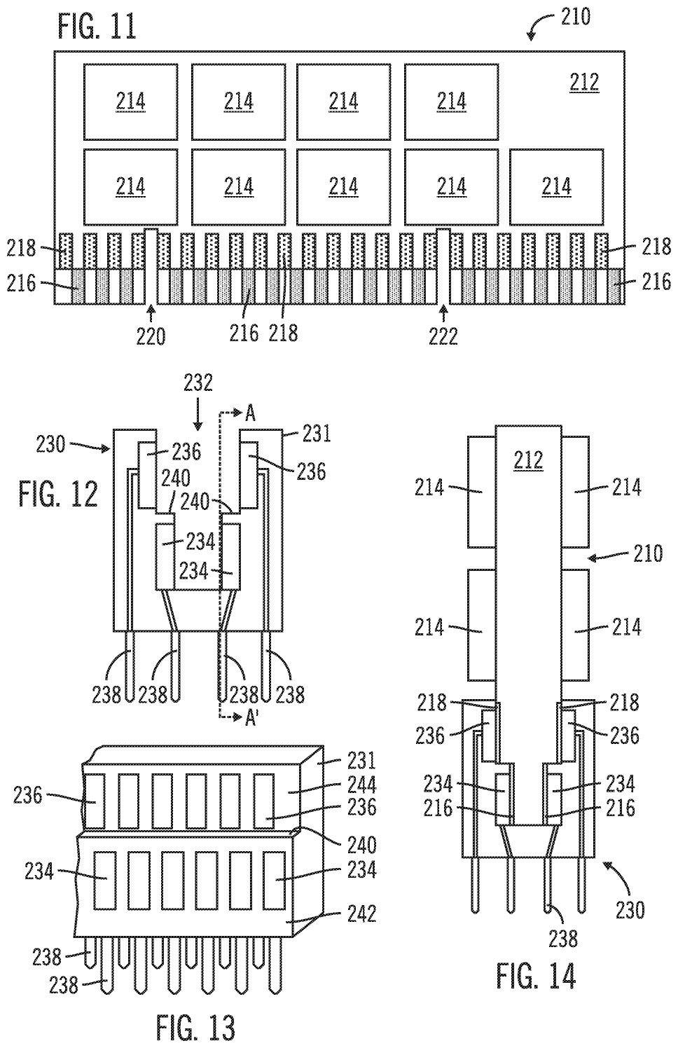

FIG. 11 illustrates an embodiment of a DIMM 210 including memory chips 214 positioned on a substrate 212, together with two rows of contacts 216, 218, and key regions 220, 222. The memory chips 214 may be the same or similar to those in the embodiment illustrated in FIGS. 1-2. The substrate 212 may have a similar multi-level structure as the substrate 12 in FIGS. 1-2. However, the contacts 216, 218 are arranged differently than the contacts 16, 18 in FIGS. 1-2. The contacts 216, 218 are positioned so that the contacts 216 and the contacts 218 are offset from each other. Whereas the contacts 16, 18 in FIG. 1 are aligned with one another, the contacts 216, 218 in the embodiment illustrated in FIG. 11 are offset so that, for example, the contacts 216 in the lower row are aligned with the spaces between the contacts 218 in the upper row. While in FIG. 11 the width of each of the contacts 216, 218 is illustrated as equal to the width of the spaces between the contacts 216, 218, embodiments also include configurations in which the width of the contacts is different than the width of the spaces between the contacts.

FIG. 12-13 illustrate a connector 230 configured to accept a DIMM such as the DIMM 210 of FIG. 11. The connector is in some ways similar to the connector 30 described above, and includes a housing 231 and an interior region 232 sized and shaped to accommodate a stepped DIMM structure. The connector 230 includes rows of lower pads 234 and upper pads 236 configured to engage the contacts 216 and 218 from the DIMM 210. The connector 230 may also include connections such as, for example, pins 238 for electrical connection to a board. The connection to the board may be made using any suitable mechanism, including, but not limited to, through hole and surface mount mechanisms. The connector 230 differs from the connector 30 in that that lower pads 234 and upper pads 236 are offset from each other, so that electrical connections may be made between the lower contacts 216 and the lower pads 234, and between the upper contacts 218 and the upper pads 236, as illustrated in FIG. 14, which illustrates a DIMM such as DIMM 210 positioned in the connector 230.

FIG. 13 illustrates a view of the connector 230 along the dashed line A-A′ of FIG. 12. The stepped structure of the connector 230 includes the lower pads 234 positioned on a different step (level) than the upper pads 236. As seen in FIG. 13, the lower pads 234 are positioned along the surface 242, and upper pads 236 are positioned along the surface 244. A ledge surface 240 is positioned between the surface 242 and surface 244. In addition, the pads 234 and the pads 236 are offset from each other, so that the offset contacts 216, 218 can be brought into electrical contact therewith.

FIG. 14 illustrates a view of the DIMM 210 of FIG. 11 positioned in the connector 230 of FIGS. 12-13. The lower contacts 216 on the DIMM 210 are positioned in electrical contact with the lower pads 234 in the connector, and the upper contacts 218 on the DIMM 210 are positioned in electrical contact with the upper pads 236 in the connector 230.

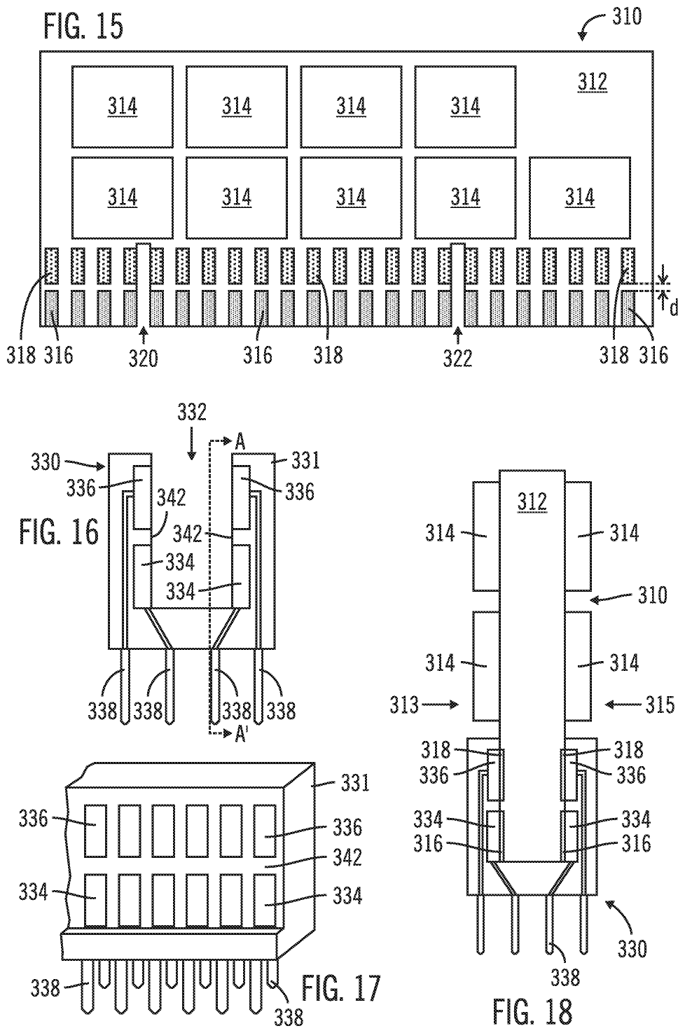

FIG. 15 illustrates an embodiment of a DIMM 310 including memory chips 314 positioned on a substrate 312, together with two rows of contacts 316, 318, and key regions 320, 322. The memory chips 314 may be the same or similar to those in the embodiment illustrated in FIGS. 1-2. The substrate 312 is configured so that the rows of contacts 316, 318 are on the same level of the substrate 312. The contacts 316, 318 are not positioned on a stepped structure such as that illustrated in FIGS. 1-2. As illustrated in FIG. 18, the contacts 316, 318 on each side 313, 315 of the DIMM may be positioned on a common plane. The two rows of contacts 316, 318 are spaced apart by a distance d. In addition, the contacts 316, 318 are positioned to be aligned with each other.

FIG. 16-17 illustrate a connector 330 configured to accept a DIMM such as the DIMM 310 of FIG. 15. The connector 330 includes a housing 331 and lower pads 334 and upper pads 336 configured to engage the contacts 316 and 318 from the DIMM 330. The connector 330 may include an interior opening 332 having the same width at both the lower pads 334 and the upper pads 336. The lower pads 334 and the upper pads 336 on each side are positioned in the same plane. The connector 330 may also include connections such as, for example, pins 338 for electrical connection to a board.

FIG. 17 illustrates a view of the connector 330 along the dashed line A-A′ of FIG. 16. The connector 330 includes the lower pads 334 positioned along a common plane with the upper pads 336, at surface 342. The upper pads 336 are aligned with the lower pads 334.

FIG. 18 illustrates a view of the DIMM 310 of FIG. 15 positioned in the connector 330 of FIGS. 16-17. The lower contacts 316 on the DIMM 310 are positioned in electrical contact with the lower pads 334 in the connector 330, and the upper contacts 318 on the DIMM 310 are positioned in electrical contact with the upper pads 336 in the connector 330.

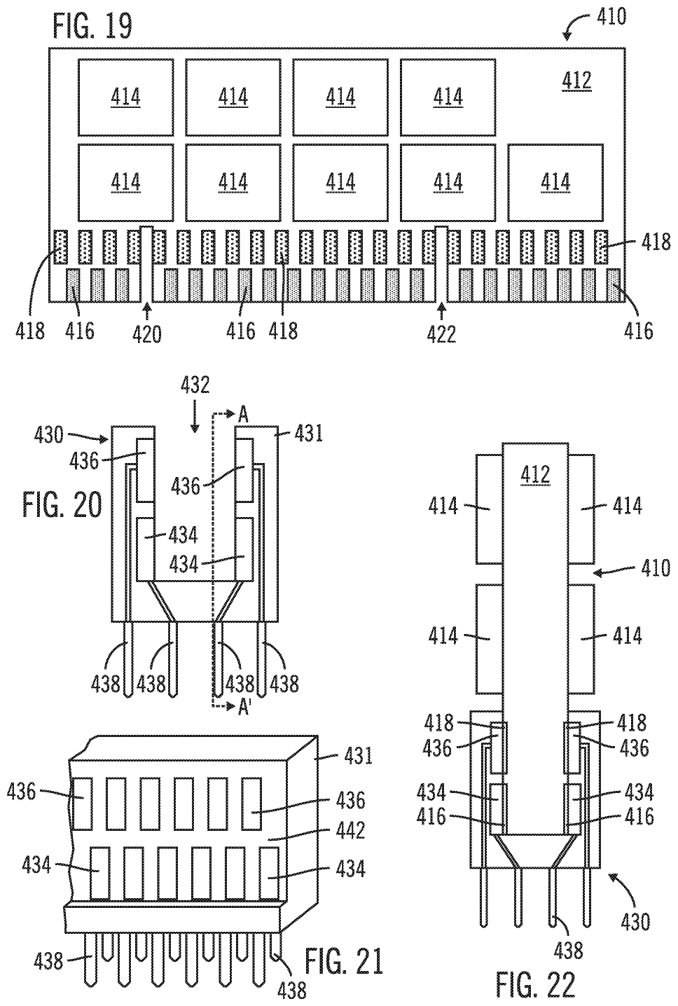

FIG. 19 illustrates an embodiment of a DIMM 410 including memory chips 414 positioned on a substrate 412, together with two rows of contacts 416, 418, and key regions 420, 422. The memory chips 414 may be the same or similar to those in the embodiment illustrated in FIGS. 1-2. The DIMM 410 may have a somewhat similar structure as the DIMM 310 in FIG. 15, where the rows of contacts 416, 418 on a side of the substrate 412 may be positioned on a common surface and are spaced apart from each other. However, the contacts 416, 418 are arranged differently than the contacts 316, 318 in FIG. 15. The contacts 416, 418 are positioned so that the first row contacts 416 and the second row contacts 418 are offset from each other. As illustrated in FIG. 19, the second row of contacts 416 are aligned with the spaces between the contacts 418 in the first row. While in FIG. 19 the width of each of the contacts 416, 418 is illustrated as equal to the width of the spaces between the contacts 416, 418, embodiments also include configurations in which the width of the contacts is different than the width of the spaces between the contacts.

FIG. 20-21 illustrate a connector 430 configured to accept a DIMM such as the DIMM 410 of FIG. 19. The connector 430 may include a housing 431 and an interior opening 432 having the same width at both the lower pads 434 and the upper pads 436. The pads 434, 436 on each interior side are positioned in the same plane on that interior side. The lower pads 434 and upper pads 436 are offset from each other, so that electrical connections may be made between the lower contacts 416 and the lower pads 434, and between the upper contacts 418 and the upper pads 436, as illustrated in FIG. 22, which illustrates a DIMM such as DIMM 410 positioned in the connector 430. The connector may also include connections such as, for example, pins 438 for electrical connection to a board.

FIG. 21 illustrates a view of the connector 430 along the dashed line A-A′ of FIG. 20. The connector 430 includes the upper pads 436 positioned along a common plane with the lower pads 434, at surface 442. The upper pads 434 are offset from the lower pads 436, so that the offset contacts 416, 418 can be brought into electrical contact therewith.

FIG. 22 illustrates a view of the DIMM 410 of FIG. 19 positioned in the connector 430 of FIGS. 20-21. The lower contacts 416 on the DIMM 410 are positioned in electrical contact with the lower pads 434 in the connector 430, and the upper contacts 418 on the DIMM 410 are positioned in electrical contact with the upper pads 436 in the connector 430.

As noted above, certain embodiments enable the formation of DIMM structures having a smaller footprint along their length. This may be accomplished by providing multiple rows of contacts on the DIMM. FIG. 23 illustrates a side cross-sectional view of a portion of a DIMM 510 in accordance with certain embodiments, including a plurality of memory chips 514 positioned on a substrate 512, together with three rows of contacts 516, 517, and 518. Any suitable number of memory chips may be provided. The DIMM 510 includes a three step (or level) structure on the sides 513, 515, with contacts 516 positioned at the step having the smallest width, then the contacts 517 positioned at the step having an intermediate width, and then the contacts 518 positioned at the step having the largest width. The contacts 516, 517, and 518 may be aligned with each other, or may be offset from each other in a manner, for example, at least somewhat similar to that described above. By providing three rows of contacts on each side, the overall length of the DIMM (and its form factor on a board) may be decreased due to all the contacts extending along a shorter length of the DIMM.

FIG. 24 illustrates a connector 530 configured to accept a DIMM such as the DIMM 510 of FIG. 23. The connector 530 may include a housing 531 and an interior opening 532 to accommodate the three rows of contacts 516, 517, 518, with electrical connections made between the lower contacts 516 and the lower pads 534, and between the intermediate contacts 517 and the intermediate pads 535, and between the upper contacts 518 and the upper pads 536. The connector 530 may also include connections such as, for example, pins 538 for electrical connection to a board.

FIG. 25 illustrates a side cross-sectional view of a portion of a DIMM 610 in accordance with certain embodiments, including a plurality of memory chips 614 (any suitable number of memory chips 614 may be provided) positioned on a substrate 612, together with three rows of contacts 616, 617, and 618. The DIMM 610 includes the three rows of contacts on each of the sides 613, 615. As illustrated in FIG. 25, the contacts 616, 617, and 618 on each side may be positioned on the same plane on that side. The contacts 616, 617, and 618 may be aligned with each other, or may be offset from each other in a manner, for example, at least somewhat similar to that described above.

FIG. 26 illustrates a connector 630 configured to accept a DIMM such as the DIMM 610 of FIG. 25. The connector 630 may include a housing 631 and an interior opening 632 to accommodate the three rows of contacts, with electrical connections made between the lower contacts 616 and the lower pads 634, between the intermediate contacts 617 and the intermediate pads 635, and between the upper contacts 618 and the upper pads 636. The connector may also include connections such as, for example, pins 638 for electrical connection to a board.

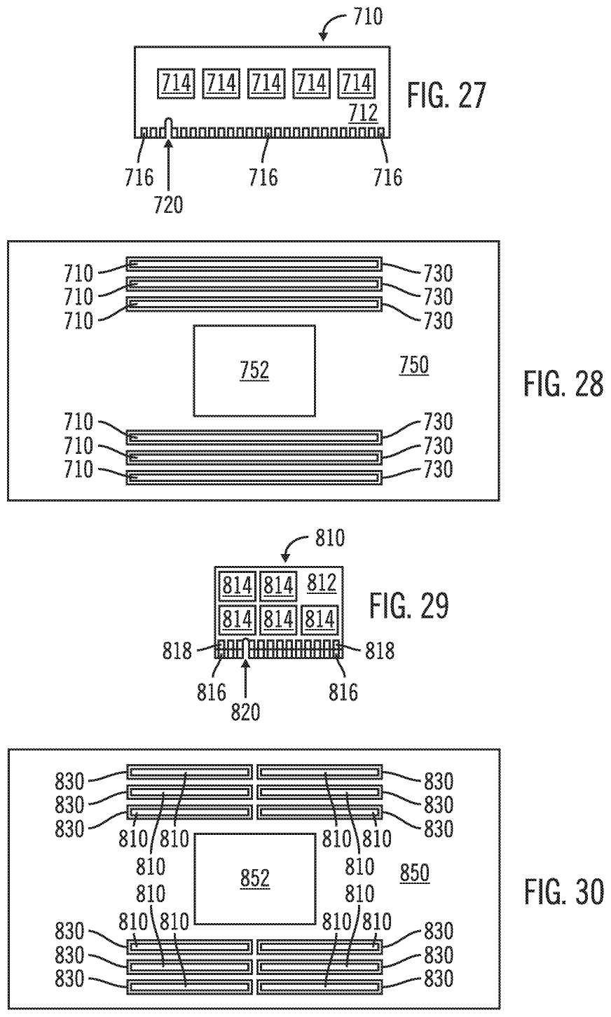

The use of DIMMs having a single row of contacts on a side versus the use of DIMMs having multiple rows of contacts on a side is illustrated in FIGS. 27-30. FIG. 27 illustrates a DIMM 710 including a plurality of memory chips 714 positioned on a substrate 712 and a single row of contacts 716 extending along the length near the bottom edge of the substrate 712, along with a key region 720. FIG. 28 illustrates a board 750 includes a microprocessor 752 mounted on the board 750 between two memory regions including DIMMs 710 positioned in connectors 730 thereon. The connectors 730 will have a different structure than the connectors described above (for example, connector 30), because the DIMMs 710 only have one row of contacts 716 on each side. Each of the memory regions of FIG. 28 includes three DIMMs 710 each positioned in a connector 730 on the board 750.

FIG. 29 illustrates a DIMM 810 including a plurality of memory chips 814 positioned on a substrate 812 and two rows of contact 816, 818 extending along a length near the bottom edge of the substrate 812, along with a key region 820, in accordance with certain embodiments (for example, similar to the embodiment illustrated in FIGS. 1-2). FIG. 30 illustrates a board 850 and includes microprocessor 852 mounted on the board 850 between two memory regions including DIMMs 810 positioned in connectors 830. The connectors 830 may have a structure similar to connectors described above that can accommodate multiple rows of DIMM contacts. When comparing the DIMMs 710 and 810, it can be seen that the DIMMs 810 include the same number of memory chips and the same number of contacts, but are only about one half the length. As a result, about two times the number DIMMs 810 can be positioned within each memory area. This is illustrated in FIGS. 28 and 30, with FIG. 28 showing three DIMMs 710 (each in connector 730) in each memory region and FIG. 30 showing six DIMMs 810 (each in connector 830) in each memory region.

By utilizing embodiments with multiple rows of contacts on each side of the DIMM, more DIMMs per unit area may be used. Whole system performance can be exploited with, for example, higher performance processors that require the additional memory that can be provided by the smaller form factor DIMMs. In applications where additional DIMMs are not necessary, the use of the smaller form factor DIMMs can save valuable board space for other components or for using a smaller form factor board.

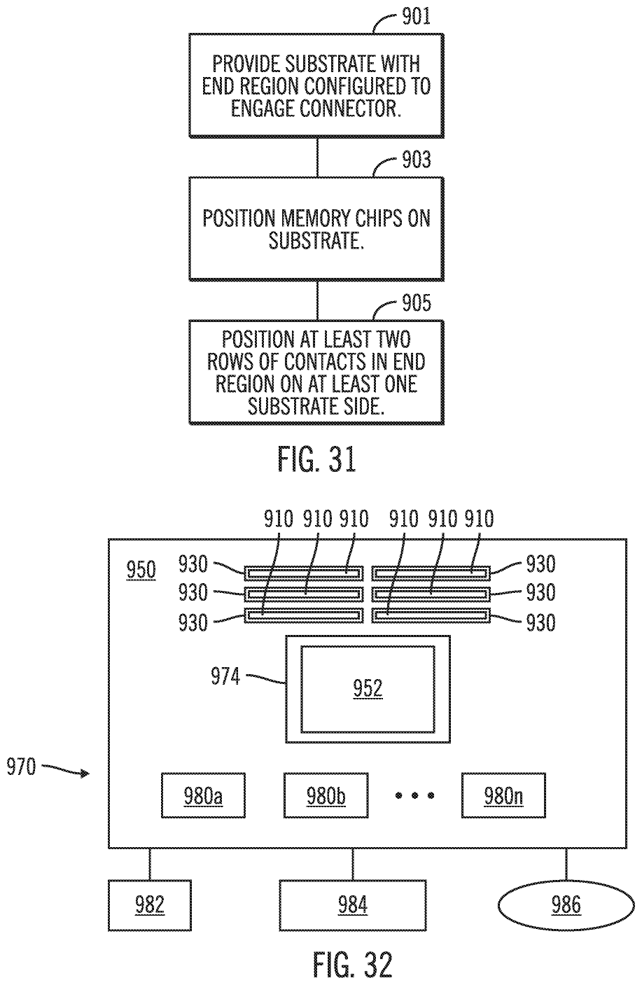

Embodiments also related to methods, including, but not limited to, methods for forming the devices described above. FIG. 31 is a flowchart of operations, in accordance with certain embodiments. Box 901 is providing a substrate such as a printed circuit board including an end region configured to engage a connector, such as described in the embodiments above. Embodiments may include a substrate including a stepped structure and multiple rows of contacts positioned on first and second surfaces of first and second sides of the substrate, such as, for example, the embodiment illustrated in FIG. 2. Another embodiment of a substrate includes a structure including multiple rows of contacts on the same surface. The surface may be planar, as illustrated, for example, in the embodiment illustrated in FIG. 18. Box 903 is providing memory chips on the substrate. Any suitable number of memory chips may be provided. The positioning of memory chips in connection with the formation of DIMMs may include a variety of configurations including, for example, two rows of memory chips on a side of the DIMM, as illustrated, for example, in FIG. 1. Another configuration includes four rows of memory chips on a side of the DIMM, as illustrated, for example, in FIG. 8. Box 905 is positioning at least two rows of contacts in the end region on at least one side of the substrate. The embodiment illustrated in FIG. 1, for example, illustrates an embodiment including two rows of contacts on both sides of the substrate. Other aspects of embodiments, including, but not limited to, providing contacts that are aligned with or offset from the contacts in a different row, may also in included in various embodiments.

Assemblies including components formed as described in embodiments above may find application in a variety of electronic components. It should be appreciated that while DIMMs are described in certain embodiments, embodiments may also relate to the use of other types of modules and connectors. In certain embodiments, memory positioned on the modules may include, for example, volatile memory including, but not limited to, DRAM (dynamic random access memory) technology such as JEDEC DDR4 and the like; and may also include, for example, non-volatile memory including, but not limited to, byte addressable three dimensional crosspoint memory.

FIG. 32 schematically illustrates one example of an electronic system environment in which aspects of described embodiments may be embodied. Other embodiments need not include all of the features specified in FIG. 32, and may include alternative features not specified in FIG. 32. The system 970 of FIG. 32 may include at least one die 952 positioned in a package substrate 974, which is then coupled to a printed circuit board 950. The system 970 includes a plurality of DIMMs 910 positioned in connectors 930. While FIG. 32 illustrates six DIMMs 910 and six connectors 930, other numbers and positions of DIMMs and connectors are possible. The DIMMs 910 and connectors 930 may be formed in accordance with embodiments such as described above. A variety of other system components may also include structures having configurations in accordance with the embodiments described above.

The system 970 may further include one or more controllers 980a, 980b . . . 980n, for a variety of components, which may also be disposed on the board 950. The system 970 may be formed with other components, including, but not limited to, storage 982, display 984, and network connection 986. The system 970 may comprise any suitable computing device, including, but not limited to, a mainframe, server, personal computer, workstation, laptop, tablet, netbook, handheld computer, handheld gaming device, handheld entertainment device (for example, MP3 (moving picture experts group layer-3 audio) player), PDA (personal digital assistant) smart phone or other telephony device (wireless or wired), network appliance, virtualization device, storage controller, network controller, router, etc.

Various features of embodiments described above may be implemented with respect to other embodiments, including apparatus and method embodiments. The order of certain operations as set forth in embodiments may also be modified. Specifics in the examples may be used anywhere in one or more embodiments.

In the foregoing description above, various features are grouped together for the purpose of streamlining the disclosure. This method of disclosure is not to be interpreted as reflecting an intention that the claimed embodiments of the invention require more features than are expressly recited in each claim. Rather, as the claims reflect, inventive subject matter may lie in less than all features of a single disclosed embodiment. Thus the claims are hereby incorporated into the Detailed Description, with each claim standing on its own as a separate embodiment.

While certain exemplary embodiments have been described above and shown in the accompanying drawings, it is to be understood that such embodiments are merely illustrative and not restrictive, and that embodiments are not restricted to the specific constructions and arrangements shown and described since modifications may occur to those having ordinary skill in the art. For example, DIMM contacts and connector pads may in certain embodiments be positioned flush with the surface they are positioned on, and in other embodiments may not be positioned flush with the surface they are positioned on. In addition, terms such as “first”, “second”, and the like may be used herein and do not necessarily denote any particular order, quantity, or importance, but are used to distinguish one element from another. Terms such as “upper”, “lower”, “top”, “bottom”, and the like may be used for descriptive purposes only and are not to be construed as limiting. Embodiments may be manufactured, used, and contained in a variety of positions and orientations.

### EXAMPLES

The following examples relate to various embodiments.

Example 1 is an apparatus including a dual in-line memory module (DIMM) comprising: a substrate including a first side and a second side; a plurality of memory chips on at least one of the first side and the second side; the first side and the second side each including an end region configured to engage a connector; a plurality of rows of electrical contacts positioned in the end region on the first side of the substrate, the plurality of rows including a first side first row of electrical contacts and a first side second row of electrical contacts; and a plurality of rows of electrical contacts positioned in the end region on the second side of the substrate, the plurality of rows including a second side first row of electrical contacts and a second side second row of electrical contacts.

In Example 2, the subject matter of Example 1 can optionally include wherein the end region on the first side of the substrate includes a leading edge, wherein the first side second row of electrical contacts is positioned a greater distance from the leading edge than the first side first row of electrical contacts.

In Example 3, the subject matter of any of examples 1-2 can optionally include wherein the end region on the first side defines a stepped structure including a first side first level and a first side second level, wherein the first side first row of electrical contacts is positioned on the first side first level, and the first side second row of electrical contacts is positioned on the first side second level.

In Example 4, the subject matter of example 3 can optionally include a ledge between the first side first level and the first side second level.

In Example 5, the subject matter of any one of examples 3-4 can optionally include wherein the end region on the second side defines a stepped structure including a second side first level and a second side second level, wherein the second side first row of electrical contacts is positioned on the second side first level, and the second side second row of electrical contacts is positioned on the second side second level, and wherein the DIMM defines a greater thickness between the first side second level and the second side second level than between the first side first level and the second side first level.

In Example 6, the subject matter of any one of examples 1-5 can optionally include wherein the electrical contacts in the first side second row are in alignment with the electrical contacts in the first side first row.

In Example 7, the subject matter of any one of examples 1-6 can optionally include wherein the electrical contacts in the second side second row are in alignment with the electrical contacts in the second side first row.

In Example 8, the subject matter of any one of examples 1-5 can optionally include wherein the electrical contacts in the first side second row are offset from the electrical contacts in the first side first row.

In Example 9, the subject matter of any one of examples 1-5 and 8 can optionally include wherein the electrical contacts in the second side second row are offset from the electrical contacts in the second side first row.

In Example 10, the subject matter of any one of examples 1-9 can optionally include wherein the electrical contacts in the first side first row each extend lengthwise in a first plane, and the electrical contacts in the first side second row each extend lengthwise in a second plane spaced apart from and parallel to the first plane.

In Example 11, the subject matter of any one of examples 1-2 can optionally include wherein the electrical contacts in the first side first row and the electrical contacts in the first side second row each extend lengthwise in a common plane.

In Example 12, the subject matter of any one of examples 1-11 can optionally include wherein the plurality of memory chips comprises two rows of memory chips on at least one of the first side and the second side.

In Example 13, the subject matter of any one of examples 1-11 can optionally include wherein the plurality of memory chips comprises four rows of memory chips on at least one of the first side and the second side.

Example 14 is a system in which the subject matter of any one of examples 1-13 can optionally further include a connector configured to accept the end regions of the DIMM, the connector including a first side first row of pads positioned to engage the first side first row of electrical contacts, a first side second row of pads positioned to engage the first side second row of electrical contacts, a second side first row of pads positioned to engage the second side first row of electrical contacts, and a second side second row of pads positioned to engage the second side second row of electrical contacts.

Example 15 is an apparatus including a dual in-line memory module (DIMM) comprising: a substrate having a first side and a second side; a plurality of memory chips positioned on at least one of the first side and the second side; the first side defining a stepped structure including a first side first level and a first side second level; the second side defining a stepped structure including a second side first level and a second side second level; the first side first level including a plurality of first side first level electrical contacts; the first side second level including a plurality of first side second level electrical contacts; the second side first level including a plurality of second side first level electrical contacts; and the second side second level including a plurality of second side second level electrical contacts.

In Example 16, the subject matter of example 15 can optionally include wherein the first side first level and the second side first level are positioned at a portion of the substrate having a first thickness, wherein the first side second level and the second side second level are positioned at a portion of the substrate having a second thickness, wherein the first thickness is greater than the second thickness.

In Example 17, the subject matter of any one of examples 15-16 can optionally include wherein the first side first level is separated from the first side second level by a ledge extending between the first side first level and the first side second level.

In Example 18, the subject matter of any one of examples 15-17 can optionally include wherein the first side first level electrical contacts are aligned with the first side second level electrical contacts.

In Example 19, the subject matter of any one of examples 15-17 can optionally include wherein the first side first level electrical contacts are offset from the first side second level electrical contacts.

Example 20 is an apparatus including a dual in-line memory module (DIMM) comprising: a substrate having a first side and a second side; a plurality of memory chips positioned on at least one of the first side and the second side; the first side and the second side each including an end region configured to engage a connector; the first side end region including a first side first row of electrical contacts and a first side second row of electrical contacts; the second side end region including a second side first row of electrical contacts and a second side second row of electrical contacts; wherein the first side first row of electrical contacts and the first side second row of electrical contacts are positioned to extend lengthwise along a common plane.

In Example 21, the subject matter of example 20 can optionally include wherein the second side first row of electrical contacts and the second side second row of electrical contacts are positioned to extend lengthwise along a common plane.

In Example 22, the subject matter of any one of examples 20-21 can optionally include wherein the first side second row of electrical contacts are positioned in alignment with the first side first row of electrical contacts.

In Example 23, the subject matter of any one of examples 20-21 can optionally include wherein the first side second row of electrical contacts are offset from the first side first row of electrical contacts.

Example 24 is a method for forming a dual in-line memory module (DIMM), comprising: providing a substrate including a first side and a second side, the first side and the second side each including an end region configured to engage a connector; positioning a plurality of memory chips on at least one of the first side and the second side; positioning a plurality of rows of electrical contacts in the end region on the first side of the substrate, the plurality of rows including a first side first row of electrical contacts and a first side second row of electrical contacts; and positioning a plurality of rows of electrical contacts in the end region on the second side of the substrate, the plurality of rows including a second side first row of electrical contacts and a second side second row of electrical contacts.

In Example 25, the subject matter of example 24 can optionally include: providing the substrate so that the end region on the first side defines a stepped structure including a first side first level and a first side second level; positioning the first side first row of electrical contacts on the first side first level; and positioning the first side second row of electrical contacts on the first side second level.

In Example 26, the subject matter of example 25 can optionally include: providing the substrate so that the end region on the second side defines a stepped structure including a second side first level and a second side second level; positioning the second side first row of electrical contacts on the second side first level; and positioning the second side second row of electrical contacts on the second side second level.

In Example 27, the subject matter of example 25 can optionally include positioning the first side first row of electrical contacts and the first side second row of electrical contacts to extend lengthwise along a common plane.

In Example 28, the subject matter of example 27 can optionally include positioning the second side first row of electrical contacts and the second side second row of electrical contacts to extend lengthwise along a common plane.

In Example 29, the subject matter of any one of examples 24-28 can optionally include positioning the first side second row of electrical contacts in alignment with the first side first row of electrical contacts.

In Example 30, the subject matter of example 29 can optionally include positioning the second side second row of electrical contacts in alignment with the second side first row of electrical contacts.

In Example 31, the subject matter of any one of examples 24-28 can optionally include positioning the first side second row of electrical contacts to be offset from the first side first row of electrical contacts.

In Example 32, the subject matter of example 31 can optionally include positioning the second side second row of electrical contacts to be offset from the second side first row of electrical contacts.

Example 33 is an apparatus including a connector configured to accept a dual in-line memory module (DIMM), comprising: a body including an opening sized to accept an end region of a DIMM; the opening defined in part by a first interior side of the body comprising two rows of pads configured to engage two rows of electrical contacts from a first side of a DIMM; and the opening defined in part by a second interior side of the body having two rows of pads configured to engage two rows of electrical contacts from a second side of a DIMM.

In Example 34, the subject matter of example 33 can optionally include wherein the first interior side includes a stepped structure including a first level and a second level, the first level comprising a first row of the two rows of pads, the second level comprising a second row of the two rows of pads.

In Example 35, the subject matter of example 34 can optionally include wherein the second interior side includes a stepped structure including a first level and a second level, the second interior side first level comprising a first row of the two rows of pads, the second level comprising a second row of the two rows of pads.

In Example, 36, the subject matter of example 33 can optionally include wherein the two rows of pads on the first interior side of the body are positioned on a common plane.

In Example 37, the subject matter of example 36 can optionally include wherein the two rows of pads on the second interior side of the body are positioned in a common plane.

In Example 38, the subject matter of any one of examples 33-37 can optionally include wherein the two rows of pads on the first interior side of the body are positioned in alignment with each other.

In Example 39, the subject matter of example 38 can optionally include wherein the two rows of pads on the second interior side of the body are positioned in alignment with each other.

In Example 40, the subject matter of any one of examples 33-37 can optionally include wherein the two rows of pads on the first interior side of the body are offset from one another.

In Example 41, the subject matter of example 40 can optionally include wherein the two rows of pads on the second interior side of the body are offset from one another.

Example 42 is an apparatus including a dual in-line memory module comprising: a substrate including a first side and a second side; a plurality of memory chips on at least one on the first side and the second side; the substrate including an end region on the first side and on the second side; means for configuring a first side first row of electrical contacts and a first side second row of electrical contacts in the end region of the first side; and means for configuring a second side first row of electrical contacts and a second side second row of electrical contacts in the end region of the second side; on the first side of the substrate.

Example 43 is an apparatus comprising means to perform a method as recited in any preceding Example.

1. A dual in-line memory module (DIMM) comprising:
a substrate including a first side and a second side;
a plurality of memory chips on at least one of the first side and the second side;
the first side and the second side each including an end region configured to engage a connector;
a plurality of rows of electrical contacts positioned in the end region on the first side of the substrate, the plurality of rows including a first side first row of electrical contacts and a first side second row of electrical contacts; and
a plurality of rows of electrical contacts positioned in the end region on the second side of the substrate, the plurality of rows including a second side first row of electrical contacts and a second side second row of electrical contacts.

2. The DIMM of claim 1, wherein the end region on the first side of the substrate includes a leading edge, wherein the first side second row of electrical contacts is positioned a greater distance from the leading edge than the first side first row of electrical contacts.

3. The DIMM of claim 1, wherein the end region on the first side defines a stepped structure including a first side first level and a first side second level, wherein the first side first row of electrical contacts is positioned on the first side first level, and the first side second row of electrical contacts is positioned on the first side second level.

4. The DIMM of claim 3, wherein the end region on the second side defines a stepped structure including a second side first level and a second side second level, wherein the second side first row of electrical contacts is positioned on the second side first level, and the second side second row of electrical contacts is positioned on the second side second level, and wherein the DIMM defines a greater thickness between the first side second level and the second side second level than between the first side first level and the second side first level.

5. The DIMM of claim 1, wherein the electrical contacts in the first side second row are in alignment with the electrical contacts in the first side first row.

6. The DIMM of claim 1, wherein the electrical contacts in the first side second row are offset from the electrical contacts in the first side first row.

7. The DIMM of claim 3, wherein the electrical contacts in the first side first row each extend lengthwise in a first plane, and the electrical contacts in the first side second row each extend lengthwise in a second plane spaced apart from and parallel to the first plane.

8. The DIMM of claim 1, wherein the electrical contacts in the first side first row and the electrical contacts in the first side second row each extend lengthwise in a common plane.

9. The DIMM of claim 1, wherein the plurality of memory chips comprises two rows of memory chips on at least one of the first side and the second side.

10. The DIMM of claim 1, wherein the plurality of memory chips comprises four rows of memory chips on at least one of the first side and the second side.

11. A system including the DIMM of claim 1, further comprising a connector configured to accept the end regions of the DIMM, the connector including a first side first row of pads positioned to engage the first side first row of electrical contacts, a first side second row of pads positioned to engage the first side second row of electrical contacts, a second side first row of pads positioned to engage the second side first row of electrical contacts, and a second side second row of pads positioned to engage the second side second row of electrical contacts.

12. A dual in-line memory module (DIMM) comprising:
a substrate including a first side and a second side;
a plurality of memory chips positioned on at least one of the first side and the second side;
the first side defining a stepped structure including a first side first level and a first side second level;
the second side defining a stepped structure including a second side first level and a second side second level;
the first side first level including a plurality of first side first level electrical contacts;
the first side second level including a plurality of first side second level electrical contacts;
the second side first level including a plurality of second side first level electrical contacts; and
the second side second level including a plurality of second side second level electrical contacts.

13. The DIMM of claim 12, wherein the first side first level and the second side first level are positioned at a portion of the substrate comprising a first thickness, wherein the first side second level and the second side second level are positioned at a portion of the substrate comprising a second thickness, wherein the first thickness is greater than the second thickness.

14. The DIMM of claim 12, wherein the first side first level is separated from the first side second level by a ledge extending between the first side first level and the first side second level.

15. The DIMM of claim 12, wherein the first side first level electrical contacts are aligned with the first side second level electrical contacts.

16. The DIMM of claim 12, wherein the first side first level electrical contacts are offset from the first side second level electrical contacts.

17-19. (canceled)

20. A method for forming a dual in-line memory module (DIMM), comprising:
providing a substrate including a first side and a second side, the first side and the second side each including an end region configured to engage a connector;
positioning a plurality of memory chips on at least one of the first side and the second side;
positioning a plurality of rows of electrical contacts in the end region on the first side of the substrate, the plurality of rows including a first side first row of electrical contacts and a first side second row of electrical contacts; and
positioning a plurality of rows of electrical contacts in the end region on the second side of the substrate, the plurality of rows including a second side first row of electrical contacts and a second side second row of electrical contacts.

21. The method of claim 20, further comprising:
providing the substrate so that the end region on the first side defines a stepped structure including a first side first level and a first side second level;
positioning the first side first row of electrical contacts on the first side first level; and
positioning the first side second row of electrical contacts on the first side second level.

22. The method of claim 20, further comprising positioning the first side first row of electrical contacts and the first side second row of electrical contacts to extend lengthwise along a common plane.

23. A connector configured to accept a dual in-line memory module (DIMM), comprising:
a body including an opening sized to accept an end region of a DIMM;
the opening defined in part by a first interior side of the body comprising two rows of pads configured to engage two rows of electrical contacts from a first side of a DIMM; and
the opening defined in part by a second interior side of the body comprising two rows of pads configured to engage two rows of electrical contacts from a second side of a DIMM.

24. The connector of claim 23, wherein the first interior side includes a stepped structure including a first level and a second level, the first level comprising a first row of the two rows of pads, the second level comprising a second row of the two rows of pads.

25. The connector of claim 23, wherein the two rows of pads on the first interior side of the body are positioned on a common plane.
